(19) United States
(12) Patent Application Publication
(10) Pub. No.: US 2025/0351277 A1
(43) Pub. Date: Nov. 13, 2025

(54) VEHICLE CONTROL UNIT

(71) Applicant: DENSO CORPORATION, Kariya-city (JP)

(72) Inventor: Takahiro ANDO, Kariya-city (JP)

(21) Appl. No.: 19/276,524

(22) Filed: Jul. 22, 2025

Related U.S. Application Data
(63) Continuation of application No. PCT/JP2024/000934, filed on Jan. 16, 2024.

(30) Foreign Application Priority Data
Feb. 14, 2023 (JP) 2023-021055

(51) Int. Cl. H05K 5/00; B60R 16/023

(52) U.S. Cl. CPC H05K 5/0026; B60R 16/0231

(57) ABSTRACT

A zone ECU, which is a vehicle control unit, includes a circuit board, an input and output module, and a power distribution circuit. The circuit board has a microcomputer including a CPU which is a processor, and power supply circuits. The input and output module that provides an input and output function is provided separately from the circuit board and has a plurality of board connection terminals and a plurality of external connection terminals that are electrically connected to an external device. The board connection terminal is electrically connected to the circuit board.

### CROSS REFERENCE TO RELATED APPLICATIONS

The present application is a continuation application of International Patent Application No. PCT/JP2024/000934 filed on Jan. 16, 2024, which designated the U.S. and claims the benefit of priority from Japanese Patent Application No. 2023-021055 filed in Japan filed on Feb. 14, 2023, the entire disclosure of the above application is incorporated herein by reference.

### TECHNICAL FIELD

The disclosure in this specification relates to a vehicle control unit.

### BACKGROUND

A plurality of ECU boards are housed in a case.

### SUMMARY

The purpose of the present disclosure is to provide a vehicle control unit that can easily change input and output functions.

One of the disclosures is a vehicle control unit with gateway functionality includes a circuit board having a processor and power supply circuitry, an input and output module having a plurality of board connection terminals and a plurality of external connection terminals and that provide input and output functions to the circuit board, and a power distribution. The board connection terminals are electrically connected to the circuit board.

### BRIEF DESCRIPTION OF DRAWINGS

FIG. 1 is a diagram showing an example of an in-vehicle network system including zone ECUs;

FIG. 2 is a diagram showing one example of an arrangement of the zone ECUs;

FIG. 3 is an exploded view of the schematic diagram of the zone ECU according to a first embodiment;

FIG. 4 is a top plan view of the zone ECU;

FIG. 5 is a cross-section view taken along a line V-V in FIG. 4;

FIG. 6 is a diagram showing an example of a relationship between an SMD connector and a board connection terminal;

FIG. 7 is a diagram showing a modified example;

FIG. 8 is a diagram showing a modified example;

FIG. 9 is a diagram showing a modified example;

FIG. 10 is a diagram showing a modified example;

FIG. 11 is a top plan view showing a zone ECU according to a second embodiment; and

FIG. 12 is a cross-sectional view taken along a line XII-XII in FIG. 11.

### DETAILED DESCRIPTION

In recent years, vehicle control units have become increasingly integrated. Due to the integration of various functions into a single vehicle control unit, in the vehicle control unit, the number of inputs and outputs, and consequently the number of terminals, increases. The number of inputs and outputs varies depending on the car model and specifications, but designing inputs and outputs for each car model and specification requires a large amount of development man-hours.

A plurality of ECU boards are electrically connected by busbars. However, each ECU board has its own connector, which is individually connected to the wiring harness. Therefore, input and output functions must be designed each time. In the above-mentioned aspects, or in other aspects not mentioned, there is a need for further improvements in the vehicle control unit.

The purpose of the present disclosure is to provide a vehicle control unit that can easily change input and output functions.

One of the disclosures is a vehicle control unit with gateway functionality includes a circuit board having a processor and power supply circuitry, an input and output module having a plurality of board connection terminals and a plurality of external connection terminals that are electrically connected to external devices and that provide input and output functions to the circuit board, and a power distribution circuit that distributes a power supply. The board connection terminals are electrically connected to the circuit board.

According to the disclosed vehicle control unit, the input and output module is provided separately from the circuit board. In other words, the input and output functions are separated from the base circuit board. The input and output functions of the vehicle control unit can be easily changed by replacing and/or increasing/decreasing the input and output modules according to vehicle type, specifications, etc. For example, the number of external connection terminals and board connection terminals, the so-called input and output pins, can be changed.

The disclosed aspects in this specification adopt different technical solutions from each other in order to achieve their respective objectives. The objects, features, and advantages disclosed in this specification will become apparent by referring to following detailed descriptions and accompanying drawings.

Hereinafter, a plurality of embodiments will be described with reference to the drawings. The same reference numerals are assigned to the corresponding elements in each embodiment, and thus, duplicate descriptions may be omitted. When only a part of the configuration is described in the respective embodiments, the configuration of the other embodiments described before may be applied to other parts of the configuration. Further, not only the combinations of the configurations explicitly shown in the description of the respective embodiments, but also the configurations of the plurality of embodiments can be partially combined even when they are not explicitly shown as long as there is no difficulty in the combination in particular.

### First Embodiment

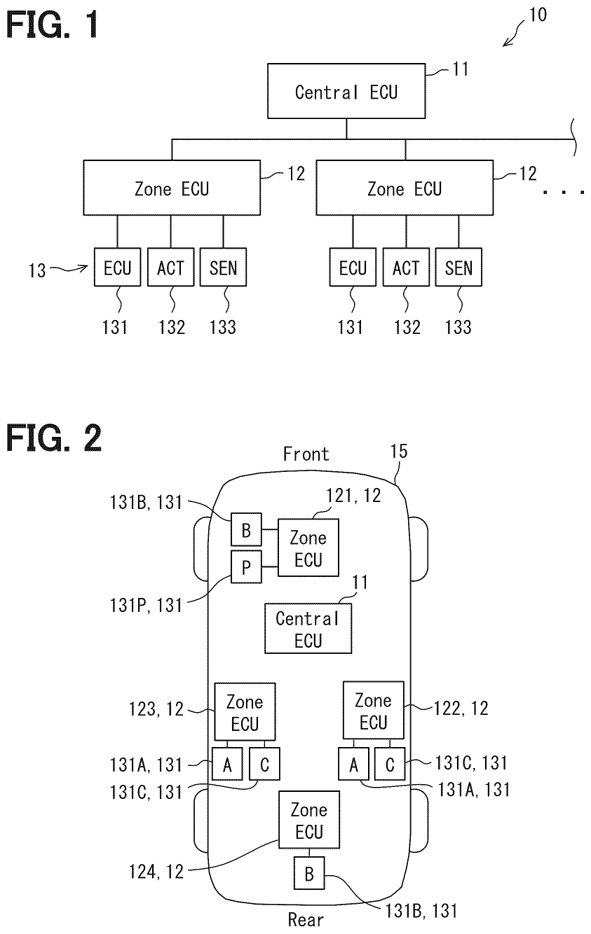

First, an in-vehicle network system including a zone ECU will be described with reference to FIGS. 1 and 2. The ECU is an abbreviation for electronic control unit. The zone ECU corresponds to a vehicle control unit. In the following description, the term “A” and/or “B” means at least one of “A” and “B”.

### In-Vehicle Network System

FIG. 1 shows an example of an in-vehicle network system including a zone ECU according to the present embodiment. As shown in FIG. 1, the in-vehicle network system 10 includes a central ECU 11, a plurality of zone ECUs 12, other devices 13, and communication lines. The in-vehicle network system 10 may be referred to as a communication system.

The central ECU 11 is a higher-level ECU than the zone ECUs 12. The central ECU 11 controls the plurality of zone ECUs 12 in an integrated manner. The central ECU 11 generates commands (control signals) for controlling the devices 13 and transmits them to the corresponding zone ECUs 12. The central ECU 11 controls the device 13 via the zone ECU 12.

Each zone ECU 12 is disposed in each of a plurality of zones set in the vehicle. The zone ECU 12 controls the device 13 arranged in the corresponding zone. The zone ECU 12 controls the corresponding device 13 according to commands from the central ECU 11. The zone ECU 12 may execute all of the controls in accordance with commands from the central ECU 11, or may execute some of the controls without following commands from the central ECU 11. For example, for control that requires real-time performance, the zone ECU 12 may generate a control signal. For example, the zone ECU 12 may generate a target torque in engine control or MG control. MG is an abbreviation for Motor Generator.

The zone ECU 12 is connected to the central ECU 11 and other zone ECUs 12 so as to be able to communicate with each other. The zone ECU 12 is communicatively connected to a plurality of devices 13 arranged in the corresponding zone. The zone ECU 12 relays, for example, communication between the central ECU 11 and the devices 13 arranged in the corresponding zone. The zone ECU 12 relays, for example, communication between the devices 13 arranged in the corresponding zone. The zone ECU 12 has a gateway function.

The device 13 may include, for example, an ECU 131 subordinate to the zone ECU 12. In this case, the zone ECU 12 controls the actuator via the ECU 131. The device 13 may include an actuator 132. In this case, the zone ECU 12 controls the actuator 132 without passing through the ECU 131. The device 13 may include a sensor 133. The zone ECU 12 acquires a detection signal from the sensor 133, for example. The device 13 includes the ECU 131 and/or the actuator 132 as objects controlled by the single zone ECU 12. The device 13 may include a plurality of control objects, for example a plurality of ECUs 131. The zone ECU 12 may acquire the detection signal of the sensor via the ECU 131. The central ECU 11 may directly acquire detection signals from some of the multiple sensors arranged in the vehicle without passing through the zone ECU 12.

The zone ECU 12 communicates with the central ECU 11, other zone ECUs 12, and devices 13 arranged in the corresponding zones in accordance with a predetermined communication protocol. As an example, the zone ECU 12 of the present embodiment communicates with the central ECU 11 and other zone ECUs 12 in accordance with the ETHERNET protocol. ETHERNET is a registered trademark. The zone ECU 12 communicates with the ECU 131 and the actuator 132 in accordance with the CAN protocol. CAN is a registered trademark and is an abbreviation for Controller Area Network. The zone ECU 12 communicates with at least some of the sensors 133 in accordance with the LIN protocol. LIN is an abbreviation for Local Interconnect Network. The zone ECU 12 may communicate with some of the sensors 133, such as a camera, millimeter wave radar, LiDAR, etc., in accordance with the CAN protocol or the ETHERNET protocol. The LIDAR stands for Light Detection and Ranging/Laser Imaging Detection and Ranging.

FIG. 2 shows an example of the arrangement of the zone ECU 12 in a vehicle. For convenience, FIG. 2 shows only the ECU 131 of the devices 13 connected to the zone ECU 12. Further, the communication lines connecting the central ECU 11 and the zone ECUs 12 and the communication lines connecting the zone ECUs 12 with each other are omitted.

A plurality of zones are set in the vehicle 15. The vehicles 15 are divided into a number of zones. A zone may also be referred to as an area, region, section, etc. The zone ECU 12 is disposed in each zone. The zone ECU 12 controls a plurality of devices 13 disposed in the corresponding zone. The number of zones and their locations on the vehicle are not particularly limited. The zones can be set arbitrarily. When the number of zones increases or decreases, the number of zone ECUs 12 also increases or decreases accordingly. The location of the central ECU 11 is not particularly limited. For example, the length of the wire harness to each zone ECU 12 is taken into consideration.

As an example, in the present embodiment, the vehicle 15 is divided into four zones: the front side of the vehicle, the right side of the cabin, the left side of the cabin, and the rear side of the vehicle. The in-vehicle network system 10 includes one central ECU 11 and four zone ECUs 12. The zone ECU 12 includes zone ECUs 121, 122, 123, and 124.

The zone ECU 121 is disposed in a zone at the front side of the vehicle. The zone ECU 121 is communicatively connected to the ECUs 131, such as a body ECU 131B and a powertrain ECU 131P. The body ECU 131B controls the body system elements on the front side of the vehicle. The body ECU 131B controls, for example, a power window device, a keyless entry device, a wiper device, and a headlight. The powertrain ECU 131P controls, for example, driving sources such as an engine and an MG (Motor Generator), a transmission, and the like.

The zone ECU 122 is disposed in the zone on the right side of the cabin. The zone ECU 122 is communicatively connected to ECUs such as the cockpit ECU 131C and the ADAS ECU 131A. The cockpit ECU 131C controls, for example, a meter device, a navigation device, an air conditioning device, and the like. The ADAS ECU 131A executes control to assist the driver's driving operation. ADAS is an abbreviation for Advanced Driving Assistant System. The ADAS ECU 131A enables advanced driving assistance of about level 2 or partial automated driving at automated driving levels defined by the Society of Automotive Engineers. For example, level 1 is a level that supports either steering or acceleration/deceleration. Level 2 is a level that supports both steering and acceleration/deceleration.

The zone ECU 123 is disposed in the left side zone of the cabin. The zone ECU 123, like the zone ECU 122, is communicatively connected to the cockpit ECU 131C and the ADAS ECU 131A.

The zone ECU 124 is disposed in the rear side zone of the vehicle. The zone ECU 124 is communicatively connected to an ECU 131, such as a body ECU 131B. The body ECU 131B controls the body system elements on the rear side of the vehicle. The body ECU 131B controls, for example, a power window device, a trunk device, a tailgate device, and brake lights.

Each of the zone ECUs 12 includes a processor, a memory, a storage, an input/output circuit, and the like. The processor is, for example, a CPU. The CPU is an abbreviation of a central processing unit. The processor accesses the memory to execute various processes for implementing functions. The memory is a volatile storage medium, such as a RAM. The RAM is an abbreviation of a random access memory.

The storage includes a nonvolatile storage medium such as a flash memory. The storage stores a control program executed by the processor. Execution of a control program by a processor corresponds to the execution of a control method corresponding to the control program. The storage appropriately stores various parameters such as threshold values used for judgment and initial values used for calculation, as well as maps and functions used for calculation. The central ECU 11 and the ECU 131 have the same configuration as the zone ECU 12.

### Zone ECU Structure

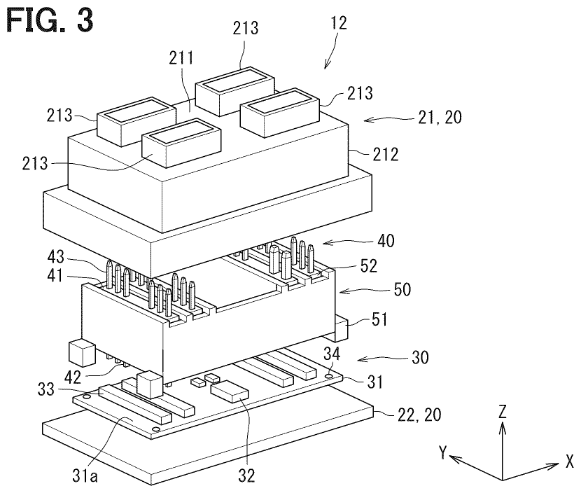

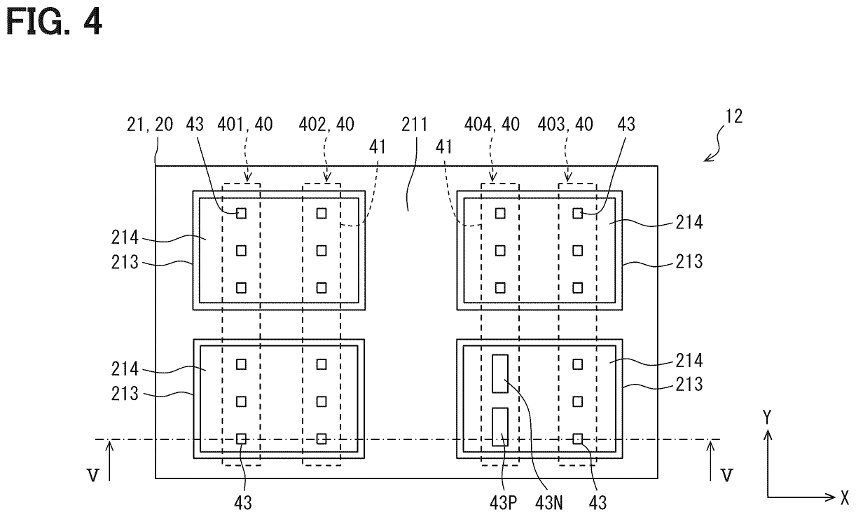

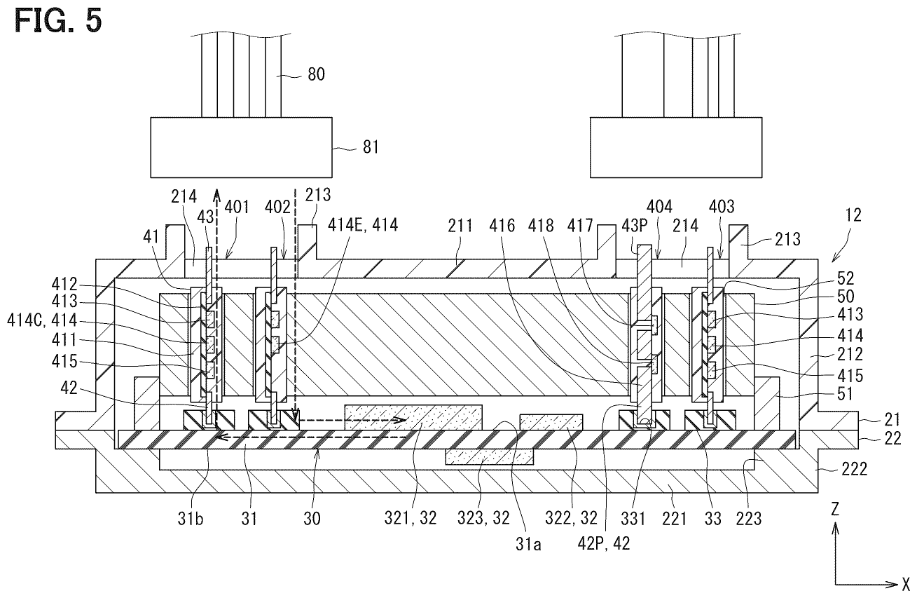

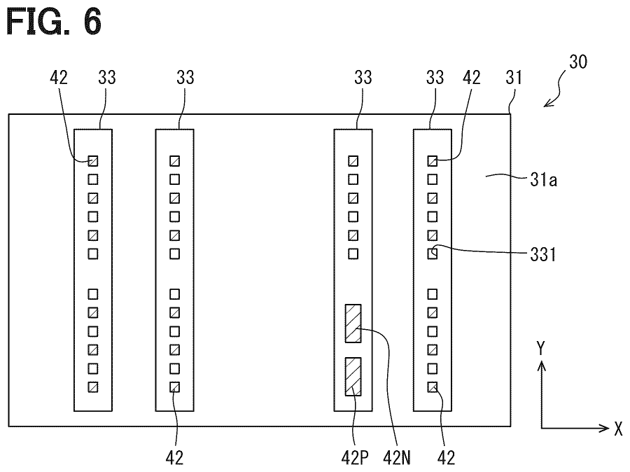

Next, the structure of the zone ECU 12 will be described with reference to FIGS. 3 to 6. FIGS. 3 to 6 show an example of a structure that can be applied to the above-mentioned zone ECU 12. FIG. 3 is an exploded perspective view showing a schematic configuration of the zone ECU 12. For convenience, the cover is shown in a simplified manner in FIG. 3. Also, some of the electronic components mounted on the board are omitted. FIG. 3 also shows a wire harness and a connector connected to the zone ECU 12. FIG. 4 is a top plan view of the zone ECU 12. FIG. 5 is a cross-sectional view taken along a line V-V in FIG. 4. FIG. 6 is a diagram showing an example of the relationship between an inserted portion of an SMD connector and a board connection terminal. For clarity, in FIG. 6, the inserted portions into which the board connection terminals are inserted are hatched. The numbers of the substrate connection terminals and the external connection terminals are not limited to the examples shown in FIGS. 3, 4, and 6. For convenience, a small number of connection terminals is shown.

As an example, the zone ECU 12 of the present embodiment includes a housing 20, a circuit board 30, an input and output module 40, and an internal holding member 50, as shown in FIGS. 3, 4, and 5. In the following, the thickness direction of the circuit board 30 is referred to as a Z-direction. Further, a direction perpendicular to the Z-direction is referred to a X-direction, and a direction perpendicular to both of the Z-direction and the X-direction is referred to a Y-direction. Unless otherwise specified, a shape viewed in a plane from the Z-direction, that is, a shape along an XY plane defined by the X-direction and Y-direction is referred to as a planar shape. A plan view from the Z direction may be simply referred to as a plan view. Furthermore, each circuit to which a reference symbol is assigned may be made into a component or IC on a circuit basis, or multiple circuits may be collectively made into an IC.

The housing 20 houses other elements that constitutes the zone ECU 12. The housing 20 houses the circuit board 30, most of the input and output module 40, and an internal holding member 50. The housing 20 is configured to include, for example, a plurality of members. As an example, the housing 20 of the present embodiment is configured to be separable in the Z-direction. The housing 20 includes a case 21 and a cover 22. The case 21 and the cover 22 are assembled together to form the housing 20 that provides a accommodation space. The case 21 and the cover 22 can be assembled together by a known method, such as snap fitting, screw fastening, or heat caulking.

The housing 20 has, for example, a substantially rectangular parallelepiped shape. The case 21 has a box shape whose one surface is open. The case 21 has a top wall 211 facing the circuit board 30 in the Z-direction, and a side wall 212 continuous with the top wall 211. The top wall 211 forms an upper wall (top wall) of the housing 20, and the side wall 212 forms a side wall of the housing 20. The side wall 212 has a cylindrical shape extending in the Z-direction, and one end in the Z-direction is connected to the top wall 211 around its entire circumference. The other end of the side wall 212 has a shape that allows it to be fixed to the cover 22, for example, a flange shape.

The case 21 has a connector housing 213 and a slot 214. The connector housing 213 and the slot 214 are provided in the top wall 211. The connector housing 213 is continuous with the top wall 211 and extends in a direction opposite to the direction from the top wall 211 to the side wall 212. The connector housing 213 is disposed so as to surround the slot 214 in a plan view. The slot 214 passes through the top wall 211 in the Z-direction. The slots 214 may be referred to as openings, through holes, or the like. The connector housing 213 constitutes a male connector together with the external connection terminals 43 exposed to the outside through the slots 214. The case 21 has four slots 214 and four connector housings 213 surrounding the slots 214 respectively. The connector has four connector ports.

As shown in FIG. 5, a female connector 81 is provided at an end of the wire harness 80. The housing of the connector 81 is fitted into the connector housing 213 and the external connection terminals 43 are connected to the terminals of the connector 81, whereby the zone ECU 12 and the wire harness 80 are electrically connected.

The cover 22 covers an opening of the case 21. The cover 22 may have a shape of, for example, a substantially flat plate or a box with one side open. The flat cover 22 may be locally provided with recesses or protrusions. As an example, the cover 22 in the present embodiment has a shallow box shape with one side open. The cover 22 has a bottom wall 221 facing the circuit board 30 in the Z-direction, and a side wall 222 continuous with the bottom wall 221. The bottom wall 221 forms a bottom wall of the housing 20, and the side wall 222 forms a side wall of the housing 20 together with the side wall 212. The side wall 222 has a cylindrical shape extending in the Z-direction, and one end in the −Z direction is connected to the bottom wall 221 around its entire periphery. The other end of the side wall 222 has a shape that allows it to be fixed to the case 21, for example, a flange shape.

The cover 22 has a support portion 223 that supports the circuit board 30 at a predetermined position within the housing 20. The support portions 223 are provided at a plurality of positions on the bottom wall 221 so as to support the circuit board 30 from the back surface 31b side. The support portion 223 protrudes in the Z-direction from the inner surface of the bottom wall 221. As an example, the support portions 223 are provided at four positions on the bottom wall 221 so as to support the four corners of the circuit board 30.

The housing 20 having the above-mentioned configurations is made of resin and/or metal. For example, both the case 21 and the cover 22 may be resin molded bodies, or both may be metal molded bodies such as aluminum die casting. One of the case 21 and the cover 22 may be a resin molded body, and the other may be a metal molded body. As an example, in the present embodiment, the case 21 is a resin molded body, and the cover 22 is a metal molded body.

In order to provide the housing 20 with a waterproof function, a sealant may be disposed thereon. The sealant is disposed, for example, between a fixed portion of case 21 and a fixed portion of cover 22, that is, in the facing region of the flanges. The sealant is disposed in the case 21 so as to close the slot 214, for example. Of the external connection terminals 43, terminals of the connector 81 are connected to the portions protruding from the sealant.

The circuit board 30 includes a printed circuit board 31, electronic components 32, and an SMD connector 33. The printed circuit board 31 may be called a wiring board, a printed wiring board, or the like. The printed circuit board 31 has, for example, a substantially rectangular shape in the plan view. As an example, the printed circuit board 31 of the present embodiment has a generally rectangular shape in the plan view with the X-direction as the longitudinal direction and the Y-direction as the lateral direction.

The printed circuit board 31 has an insulating base material and wiring. The insulating base material is made of an electrically insulating material such as a resin. The wiring is disposed on an insulating substrate. The wiring includes at least a conductor pattern. The conductor pattern is formed, for example, by patterning a metal foil. The conductor pattern may be disposed on at least one of the first surface 31a and the back surface 31b of the printed circuit board 31, or may be disposed inside the insulating substrate. The printed circuit board 31 may be a single-sided board, a double-sided board, or a multi-layer board including three or more layers of conductor patterns. The back surface 31b is the surface opposite to one surface 31a in the Z-direction.

The wiring may include a via conductor. The via conductor is formed by arranging a conductor such as plating in a through hole (via) formed in an insulating layer constituting the insulating base material. The via conductors electrically connect the conductor patterns on different layers. The wiring includes a land. The lands may include, for example, lands for surface mounting arranged as part of a conductor pattern on the surface layer of an insulating substrate. The land may include, for example, a through-hole land for insertion mounting arranged on the wall surface of a through-hole that penetrates an insulating substrate.

The electronic components 32 are mounted on the printed circuit board 31. The electronic components 32 are electrically connected to the corresponding lands by, for example, soldering. The electronic components 32 form a circuit together with the wiring of the printed circuit board 31. The circuit board 30 includes a plurality of electronic components 32. A plurality of electronic components 32 are disposed on at least one surface 31a. As an example, in the present embodiment, some of the electronic components 32 are arranged on one surface 31a, and the other parts are arranged on the back surface 31b. That is, the electronic components 32 are arranged on both sides of the printed circuit board 31.

The electronic components 32 include a processor and a power supply circuit. The processor executes a control program stored in the storage while accessing the memory, thereby implementing a plurality of functional units. The processor may be referred to as a processing unit or the like. The power supply circuit supplies power for operating other circuit elements of the zone ECU 12. The power supply circuit supplies power for operating the device 13 that is communicatively connected to the zone ECU 12. The power supply circuit is a constant voltage power supply that generates a constant voltage lower than a supply voltage based on a voltage supplied from a power supply device such as a battery. The power supply circuit may be called an internal power supply circuit. One power supply circuit may generate a single constant voltage, or may generate a plurality of constant voltages different from each other.

As an example, the electronic component 32 in the present embodiment includes a microcomputer 321 and power supply circuits 322 and 323. The microcomputer 321 includes a CPU (processor), a RAM (memory), a ROM (storage), and the like. The ROM is an abbreviation for Read Only Memory. The microcomputer 321 may be referred to as a processor module, a processor device, or the like. The microcomputer 321 is disposed on one surface 31a. The power supply circuit 322 is a primary power supply circuit, and the power supply circuit 323 is a secondary power supply circuit. The power supply circuit 322 receives power from the battery via the connector and the input and output module 40. The power supply circuit 322 generates a constant voltage lower than the power supply voltage based on the power supplied from the battery. The power supply circuit 323 generates a constant voltage lower than the voltage generated by the power supply circuit 322 based on the output of the power supply circuit 322. The power supply circuit 322 is disposed on one surface 31a, and the power supply circuit 323 is disposed on the back surface 31b. Each of the power supply circuits 322 and 323 is mounted on the printed circuit board 31 as, for example, a power supply IC.

The SMD connector 33 is disposed on one surface 31a of the printed circuit board 31. The SMD connector 33 is electrically connected to a land of the printed circuit board 31 by, for example, soldering. The SMD connector 33 has an inserted portion 331 into which a terminal is inserted. The inserted portion 331 is a so-called socket contact. The board connection terminals 42 of the input and output module 40 are inserted into the inserted portion 331. By inserting the board connection terminal 42 into the inserted portion 331, the input and output module 40 is electrically connected to the circuit board 30. The board connection terminal 42 is insertable into and removable from the SMD connector 33.

As an example, the circuit board 30 of the present embodiment has four SMD connectors 33. The circuit board 30 has the same number of SMD connectors 33 as the number of input and output modules 40. Each of the SMD connectors 33 has a plurality of inserted portions 331. The SMD connector 33 has a longitudinal direction in the Y-direction in the plan view, and the plurality of inserted portions 331 are arranged side by side in the Y-direction. The plurality of SMD connectors 33 are arranged side by side in the X-direction, which is a short side direction. Of the four SMD connectors 33, two are disposed on one end side of the printed circuit board 31 in the X direction, and the other two are disposed on the other end side. Between the two SMD connectors 33 and the other two SMD connectors 33, the electronic components 32 are disposed.

As shown in FIG. 6, the circuit board 30 has more inserted portions 331 than there are board connection terminals 42 of the input and output modules 40. The SMD connector 33 has a greater number of inserted portions 331 than the number of board connection terminals 42 of the corresponding input and output module 40. This allows replacement with the input and output module 40 having a larger number of terminals. Of course, it is also possible to replace the input and output module 40 with one having fewer terminals. The inserted portion 331 is provided with a sufficient margin for the input and output module 40 that can be inserted.

The printed circuit board 31 has fixing holes 34 for fixing the internal holding member 50 to the housing 20. As an example, the fixing holes 34 in the present embodiment are provided at the four corners of the printed circuit board 31.

The input and output module 40 provides input and output functions among the functions of the zone ECU 12. The input ad output module 40 is a module in which the input and output function is separated from the circuit board 30. The zone ECU 12 includes at least one input and output module 40. As an example, the zone ECU 12 of the present embodiment includes a plurality of (four) input and output modules 40. The input and output module 40 includes an input and output module 401, an input and output module 402, an input and output module 403, and an input and output module 404.

The connection targets of each input and output module 40 are not particularly limited. For example, the plurality of input and output modules 40 may be divided according to the connection targets. Specifically, the connection targets may be divided into a battery (power source), the central ECU 11, other zone ECUs 12, and devices 13 in the corresponding zones. The plurality of input and output modules 40 may be divided according to the positions of the connection targets. A single input and output module 40 may be configured to connect at least one of the central ECU 11, the other zone ECUs 12, and the device 13 of the corresponding zone, as well as a battery. A single input and output module 40 may be configured to connect two or more of the central ECU 11, the other zone ECUs 12, and the devices 13.

Each of the input and output modules 40 includes a main body 41, a plurality of board connection terminals 42, and a plurality of external connection terminals 43. The board connection terminals 42 and the external connection terminals 43 are formed using a metal material having excellent electrical conductivity, such as copper. The board connection terminals 42 protrude from the main body 41 and extend in a predetermined direction. The board connection terminals 42 are electrically connected to corresponding lands of the circuit board 30. The external connection terminals 43 extend from the main body 41 in the opposite direction to the board connection terminals 42. As described above, the external connection terminals 43 are exposed to the inside of the connector housing 213 through the slots 214 of the case 21, and are capable of being connected to the terminals of the connector 81.

As an example, in the present embodiment, the board connection terminal 42 protrudes from the surface of the main body 41 facing the circuit board 30 and extends in the Z-direction. The board connection terminal 42 extends toward the circuit board 30. A plurality of board connection terminals 42 provided on one input and output module 40 are aligned in the Y-direction. The external connection terminals 43 protrude from the surface of the main body 41 opposite the surface facing the circuit board 30, and extend in the Z-direction. The external connection terminal 43 extends toward the top wall 211 of the case 21. The plurality of external connection terminals 43 provided on one input and output module 40 are aligned in the Y-direction. The input and output module 40 as a whole extends in the Z-direction, that is, in the thickness direction of the circuit board 30. Hereinafter, the board connection terminal 42 and the external connection terminal 43 may be simply referred to as terminals 42 and 43.

The four input and output modules 40 are arranged in the X-direction, similar to the SMD connectors 33. Of the four input and output modules 40, two are arranged on one end side of the printed circuit board 31 in the X-direction, and the other two are arranged on the other end side. The external connection terminals 43 of the two input and output modules 40 arranged on one end side are exposed and separated into two slots 214 aligned in the Y-direction. The external connection terminals 43 of the two input and output modules 40 arranged on the other end side are exposed and separated to the other two slots 214 aligned in the Y-direction.

The main body 41 has a sealing member 411. The sealing member 411 seals the other elements that constitute the main body 41. The sealing member 411 is made of, for example, an epoxy resin. The sealing member 411 may be called a molding resin or the like. The sealing member 411 forms the outer periphery of the main body 41. The sealing member 411 is a structure common to a plurality of input and output modules 40, for example. The outer periphery of the main body 41 has, for example, a common shape and size.

The main body 41 of the input and output module 40, which communicates with at least one of the central ECU 11, the other zone ECUs 12, and the device 13 in the corresponding zone, has a printed circuit board 412, an input and output circuit 413, and a communication circuit 414. The main body 41 of the input and output module 40 that communicates with the device 13 in the corresponding zone further includes a power distribution circuit 415.

The terminals 42 and 43 are connected to the printed circuit board 412. The input and output circuit 413 performs general-purpose input and output processing. The communication circuit 414 executes processes for communicating with the central ECU 11, other zone ECUs 12, and the devices 13 in the corresponding zones. The communication circuit 414 converts electrical signals, for example, to perform communication in accordance with a predetermined protocol. The communication circuit 414 switches the communication target in response to an instruction from the microcomputer 321, for example.

As an example, the input and output module 401 has a communication circuit 414C for CAN as the communication circuit 414. The input and output module 402 includes a communication circuit 414E for ETHERNET as the communication circuit 414. The communication circuit 414C may be referred to as a CAN transceiver. The communication circuit 414C enables two-way communication by converting electrical characteristics between the communication bus (wire harness 80) and the microcomputer 321. The communication circuit 414E has the functions of a PHY and a switch. The PHY converts between analog signals for communication conforming to the Ethernet standard and digital signals of the MAC. MAC is an abbreviation for Media Access Controller.

For example, as indicated by the dashed arrow in FIG. 5, a command from the central ECU 11 is processed by the input and output module 402, then converted from the ETHERNET protocol to the CAN protocol by the microcomputer 321, and transmitted to the corresponding device 13 via the input and output module 401. When the zone ECU 12 communicates with the device 13 in accordance with the LIN, one of the input and output modules 40 includes the communication circuit 414 for the LIN (not shown).

The power distribution circuit 415 distributes the power supplied from the battery to the plurality of devices 13 corresponding to the power distribution circuit 415. The power distribution circuit 415 may directly distribute a part of the power supplied from the battery, or may indirectly distribute the power via the power supply circuits 322 and 323. For example, the input and output modules 401 and 403 each include the power distribution circuit 415. In a configuration in which the input and output module 402 communicates with the device 13, the input and output module 402 is also provided with the power distribution circuit 415.

The input and output module 40, which receives power from the battery, has a bus bar 416 and a reverse connection protection circuit 417. As an example, the input and output module 404 includes a bus bar 416 and a reverse connection protection circuit 417. The input and output module 404 corresponds to a power supply module. The bus bar 416 is a metal plate. Most of the bus bar 416 is sealed with the sealing member 411, and the portions protruding from the sealing member 411 form the terminals 42 and 43. The battery is electrically connected to the terminals 42 and 43 of the bus bar 416. In the figure, the terminals 42 and 43 electrically connected to the battery have a P or N added to their ends. The terminals 42P and 43P are terminals of the bus bar 416 that is connected to the positive electrode of the battery. The terminals 42N and 43N are terminals of the bus bar 416 that is connected to the negative electrode of the battery.

A large current of, for example, 60 A or more flows through the terminals 42N, 42P, 43N, and 43P. For this reason, the bus bar 416 having a larger diameter, i.e., a larger cross-sectional area, than the other terminals 42, 43 is employed. As an example, the input and output module 404 has a terminal of a bus bar 416 having a large diameter and other terminals 42 and 43 having a small diameter.

The reverse connection protection circuit 417 protects the circuit of the zone ECU 12 when the battery is mistakenly connected in the reverse polarity. As the reverse connection protection circuit 417, for example, a diode for reverse connection protection, a MOSFET with a built-in PN diode, or the like can be used. The reverse connection protection circuit 417 is provided in the current path of the bus bar 416. MOSFET is an abbreviation for Metal Oxide Semiconductor Field Effect Transistor.

The input and output module 40 may further include a current monitoring circuit 418. The current monitoring circuit 418 monitors the current, and when the current exceeds a threshold value, turns off a semiconductor switch such as a MOSFET to cut off the current. This makes it possible to suppress a damage to the wire harness 80. The current monitoring circuit 418 may be provided in the input and output module 40 through which particularly large current flows. In the present embodiment, the current monitoring circuit 418 is provided in the current path of the bus bar 416. The current monitoring circuit 418 may be provided in the current path of the power distribution circuit 415.

The above-mentioned printed circuit board 412, input and output circuit 413, communication circuit 414, power distribution circuit 415, most of the bus bar 416, reverse connection protection circuit 417, and current monitoring circuit 418 are sealed by the sealing member 411.

The internal holding member 50 is disposed inside the housing 20, i.e., in the accommodation space. The internal holding member 50 is fixed directly or indirectly to the housing 20. As an example, the internal holding member 50 of the present embodiment has a fixing portion 51. The fixing portion 51 is screwed to the cover 22 through the fixing hole 34 of the circuit board 30.

The internal holding member 50 has a slot 52 in which the input and output module 40 is placed. The input and output module 40 is inserted into the slot 52. With the input and output module 40 connected to the circuit board 30, the main body 41 is disposed inside the slot 52. The internal holding member 50 holds the input and output module 40 within the slot 52. The internal holding member 50 is formed using, for example, a resin material and/or a metal material.

The number of input and output modules 40 held in each slot 52 is not particularly limited. One input and output module 40 may be arranged in one slot 52, or multiple input and output modules 40 may be arranged in one slot 52. As an example, the internal holding member 50 of the present embodiment has the same number of slots 52 as the number of input and output modules 40. In each slot 52, a corresponding input and output module 40 is disposed. The slots 52 extend in the Z direction and are open at the top and bottom of the internal holding member 50 which has a substantially rectangular parallelepiped shape. At least a portion of the board connection terminal 42 is located below the lower surface of the internal holding member 50, that is, on the circuit board 30 side. At least a portion of the external connection terminal 43 is located above the upper surface of the internal holding member 50 and is disposed within the connector housing 213. In the present embodiment, the housing 20 and the internal holding member 50 correspond to the holding member having the slot.

### Summary of First Embodiment

According to the zone ECU 12 (vehicle control unit) of the present embodiment, the input and output module 40 is provided separately from the circuit board 30. In other words, the input and output function is separated from the circuit board 30 which is the base. By replacing the input and output module 40 according to the vehicle model and specifications, the input and output functions of the zone ECU 12 can be easily changed. For example, multiple types of input and output modules 40 can be prepared in advance and selected according to the vehicle model and specifications so as to eliminate the need to change the input and output design each time. By changing the input and output module 40, the number of board connection terminals 42 and external connection terminals 43, that is, the number of input and output pins, can be easily changed.

The zone ECU 12 may include at least a circuit board 30 having the microcomputer 321 (processor) and power supply circuits 322 and 323, input and output module 40, and the power supply distribution circuit 415. As an example, the zone ECU 12 of the present embodiment includes the housing 20 having the slot 214 in the top wall 211. The external connection terminal 43 of the input and output module 40 is held in the slot 214 and can be connected to an external device. The external connection terminal 43 provides a connector together with the housing 20. Therefore, by replacing the input and output module 40 held in the slot 214, the specifications of the connector can also be changed.

As an example, the zone ECU 12 of the present embodiment includes the internal holding member 50 having the slot 52. The main body 41 of the input and output module 40 is held in the slot 52. This makes it possible to easily change the input and output function by replacing the input and output module 40 inserted into the slot 52. Furthermore, the internal holding member 50 makes it possible to stably hold the input and output module 40 within the housing 20.

The zone ECU 12 includes the communication circuit 414. The zone ECU 12 may include a plurality of communication circuits 414 of a single system, or may include a plurality of communication circuits 414 of the same type. As an example, the zone ECU 12 of the present embodiment includes a plurality of communication circuits 414. This allows the zone ECU 12 to relay communications between multiple systems. For example, the zone ECU 122 can relay communications between the cockpit system and the ADAS system. As an example, the zone ECU 12 of the present embodiment includes a plurality of types of communication circuits 414. For example, the zone ECU 12 includes at least two of a communication circuit 414C for CAN, a communication circuit 414E for ETHERNET, and a communication circuit for LIN. This allows the zone ECU 12 to relay communications between different protocols.

The number of devices 13 corresponding to the zone ECU 12 may be one, or a plurality of devices 13 may be provided for redundancy. As an example, the processor of the zone ECU 12 in the present embodiment, that is, the microcomputer 321, performs input and output to and from a plurality of devices 13 having different functions. In other words, a plurality of devices 13 having different functions are electrically connected to the external connection terminal 43. In this manner, the zone ECU 12 can relay communications between a plurality of devices 13 having different functions. The multiple devices 13 are, for example, an ECU 131 and an actuator 132 of the same system. The multiple devices 13 are, for example, ECUs 131 of different systems. The multiple devices 13 are at least two of a body ECU 131B, a powertrain ECU 131P, a cockpit ECU 131C, and an ADAS ECU 131A.

The number of inserted portions of the circuit board 30 into which the board connection terminals 42 are inserted may be changed in accordance with changes to the input and output modules 40, that is, changes to the board connection terminals 42. As an example, the circuit board 30 of the present embodiment has the inserted portions 331 which are greater in number than the board connection terminals 42. As shown in FIG. 6, the inserted portions 331 are provided in a large number with a margin, taking into consideration the specifications and vehicle models to which they are applied. Therefore, even if the number of board connection terminals 42 varies depending on the specifications or vehicle model, the inserted portion 331, i.e., the circuit board 30, does not need to be changed. The number of terminals can be easily changed.

The zone ECU 12 includes, as the input and output module 40, a power supply module that is electrically connected to a battery (on-board power supply). As an example, the zone ECU 12 of the present embodiment includes the input and output module 404 which is a power supply module. The diameter of the board connection terminals 42N, 42P connected to the battery is made longer than the diameter of the other board connection terminals 42. Further, the diameter of the external connection terminals 43N, 43P connected to the battery is made longer than the diameter of the other external connection terminals 43. Therefore, it is suitable as the zone ECU 12 having a power distribution function. It is particularly suitable for the zone ECU 12 that can handle a maximum direct current (large current) of 60 A or more.

The arrangement of the input and output module 40 on the circuit board 30 is not particularly limited. For example, the input and output module 40 may be disposed substantially parallel to the circuit board 30. In the present embodiment, as an example, the input and output module 40 extends in a direction intersecting with the surface 31a of the circuit board 30. This makes it possible to suppress an increase in the size of the zone ECU 12 in a direction perpendicular to the Z direction, for example. In particular, in the present embodiment, the input and output module 40 extends approximately parallel to the Z direction, which is the thickness direction of the circuit board 30. This enhances the effect of suppressing physical growth. Moreover, the input and output module 40 can be easily replaced.

The zone ECU 12 may include at least one input and output module 40. For example, a configuration including only one input and output module 40 may be used. As an example, the zone ECU 12 of the present embodiment includes a plurality of input and output modules 40. This allows greater freedom in input and output design compared to a configuration in which input and output is consolidated into one module.

The zone ECU 12 includes the input and output circuit 413, the communication circuit 414, and the power distribution circuit 415 in order to provide a gateway function and a power distribution function. At least one of these circuits 413, 414, and 415 may be mounted on the circuit board 30. As an example, in the zone ECU 12 of the present embodiment, the input and output circuit 413, the communication circuit 414, and the power distribution circuit 415 are provided in one of the multiple input and output modules 40. For example, the input and output modules 401 and 403 are provided with the input and output circuit 413, the communication circuit 414, and the power distribution circuit 415. The input and output module 402 includes at least an input and output circuit 413 and the communication circuit 414. In this way, by providing the input and output circuit 413, the communication circuit 414, and the power distribution circuit 415 in the input and output module 40, the communication function and the power distribution function can be easily changed by replacing the input and output module 40.

In the zone ECU 12, the wire harness 80 is connected to the external connection terminal 43. As an example, the zone ECU 12 of the present embodiment includes the current monitoring circuit 418 in the input and output module 40. The current monitoring circuit 418 is provided in the current path of the bus bar 416, for example. The current monitoring circuit 418 monitors the current flowing through the bus bar 416, and when the current exceeds a threshold value, turns off the semiconductor switch to cut off the flow of electricity. This makes it possible to suppress a damage to the wire harness 80.

The connection structure (mounting structure) between the circuit board 30 and the board connection terminals 42 is not particularly limited. As an example, in the zone ECU 12 of the present embodiment, the board connection terminal 42 is inserted into the inserted portion 331 of the SMD connector 33 and is electrically connected to the circuit board 30. The board connection terminals 42 are insertable into and removable from the circuit board 30. Therefore, even if the program is rewritten (reprogrammed) using OTA technology, the input and output functions can be changed by replacing the input and output module 40 at a dealer or the like. The OTA is an abbreviation of over the air.

### Modified Example

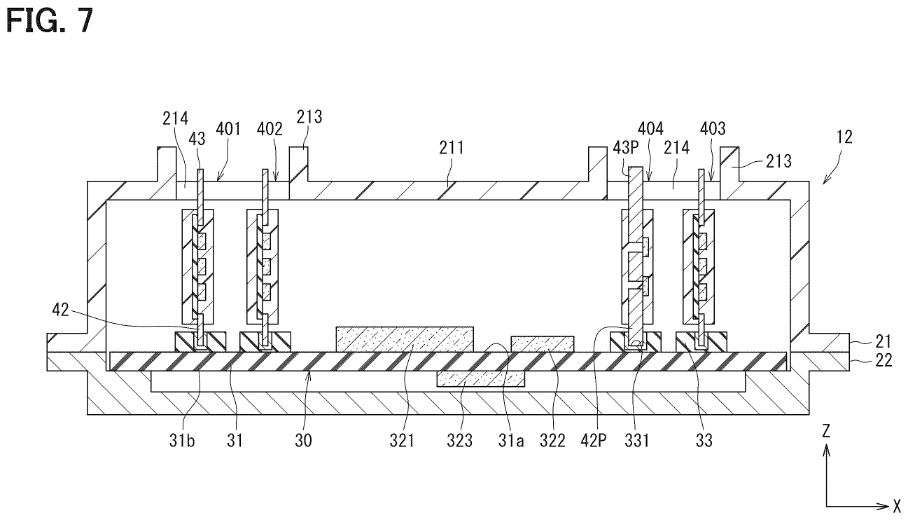

Although an example in which the zone ECU 12 includes the internal holding member 50 has been shown, the present disclosure is not limited to this configuration. For example, as shown in FIG. 7, the internal holding member 50 may be eliminated. FIG. 7 corresponds to FIG. 5. In this configuration, the external connection terminal 43 is held in the slot 214 of the housing 20 (case 21). The housing 20 corresponds to a holding member. In the configuration shown in FIG. 7, the storage space of the housing 20 may be filled with gel, potting resin, or the like, taking into consideration heat dissipation and connection reliability.

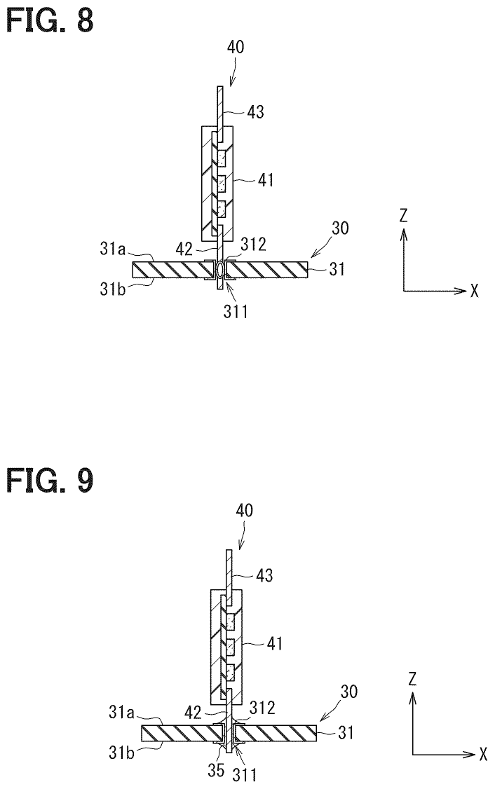

Although an example in which the SMD connector 33 is used as a configuration in which the board connection terminal 42 can be inserted into and removed from the circuit board 30 has been shown, the present disclosure is not limited to this configuration. For example, as shown in FIG. 8, a press-fit terminal may be used as the board connection terminal 42. FIG. 8 corresponds to the mounting structure of the input and output module 40 shown in FIG. 5. The circuit board 30 (printed circuit board 31) has a through hole 311 penetrating in the Z direction and a through hole land 312 formed on the wall surface of the through hole 311. The board connection terminal 42 is inserted into the through hole 311, and contacts and is electrically connected to the through hole land 312 due to the reaction force of elastic deformation. In addition, in FIG. 8, a needle-eye shaped press-fit terminal is used, but the shape is not limited to thereto.

Rather than being designed for insertion and removal, the board connection terminals 42 may be soldered to the circuit board 30. For example, as shown in FIG. 9, an insertion mounting structure may be adopted. FIG. 9 corresponds to FIG. 8. The board connection terminal 42 is inserted into the through hole 311 and joined to the through hole land 312 by solder 35. This can improve the reliability of the connection between the input and output module 40 and the circuit board 30.

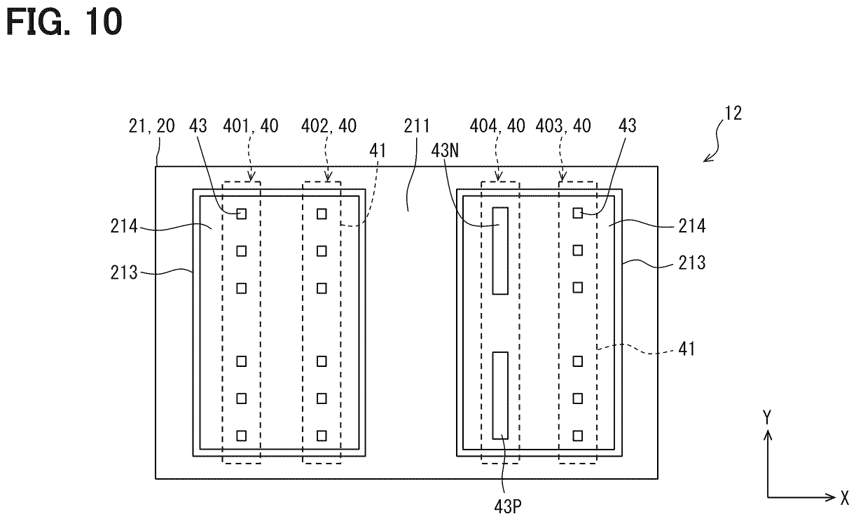

The number, positions and planar shapes of the connector housings 213 in the housing 20 are not limited to the above example. Appropriate settings can be made taking into consideration the connection target. For example, as shown in FIG. 10, a configuration having two connector housings 213 may be used. FIG. 10 corresponds to FIG. 4. The external connection terminals 43 of the two input and output modules 40 arranged on one end side of the printed circuit board 31 are exposed from one of the slots 214. The external connection terminals 43 of the two input and output modules 40 arranged on the other end side are exposed from the other one of the slots 214. In FIG. 10, the input and output module 404 is a module dedicated to power supply, and includes only external connection terminals 43N and 43P connected to a battery as the external connection terminals 43.

### Second Embodiment

A second embodiment is a modification of the preceding embodiment as a basic configuration and may incorporate description of the precedent embodiments. In the preceding embodiment, an example was shown in which the input and output modules were replaced depending on the vehicle model and specifications. Alternatively or additionally, more or fewer input and output modules may be used.

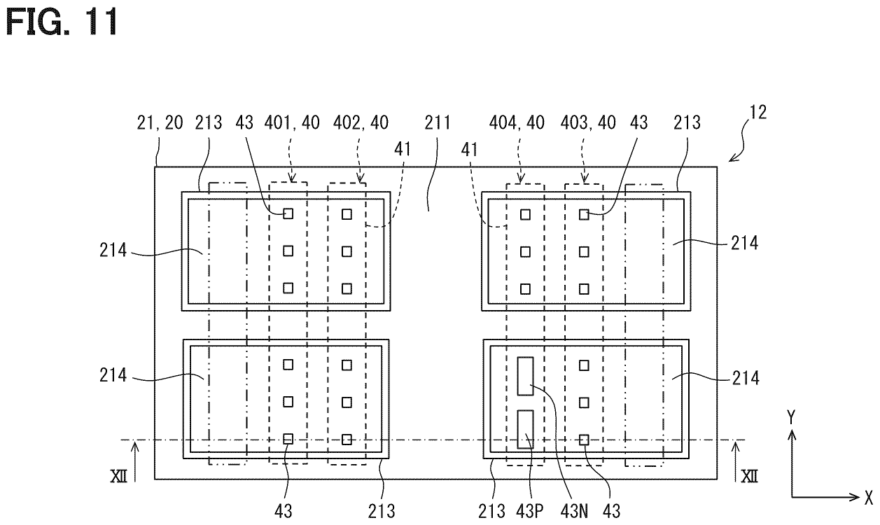

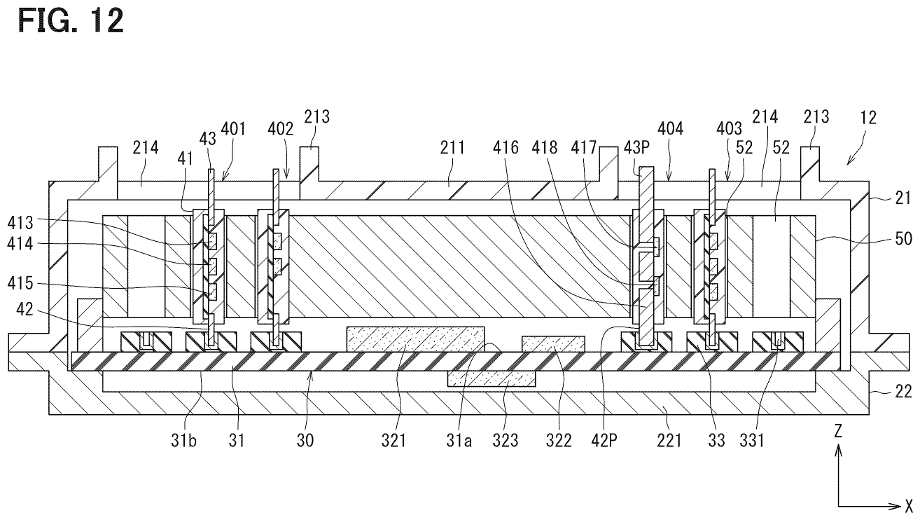

FIG. 11 is a top plan view showing the zone ECU 12 according to the present embodiment. FIG. 11 corresponds to FIG. 4. Each of the two-dot chain lines shown in FIG. 11 indicates an empty space (blank) in the input and output module 40. FIG. 12 is a cross-sectional view taken along a line XII-XII in FIG. 11. FIG. 12 corresponds to FIG. 5.

As shown in FIGS. 11 and 12, the zone ECU 12 can include up to six input and output modules 40. In the example shown in FIGS. 11 and 12, the zone ECU 12 includes four input and output modules 40. The connector housing 213 and the slot 214 are provided corresponding to three input/output modules 40, respectively. The circuit board 30 is provided so as to be connectable to six input and output modules 40. As an example, the circuit board 30 has six SMD connectors 33. The SMD connector 33 has the same number of inserted portions 331 as the number of board connection terminals 42 of the corresponding input and output module 40.

The internal holding member 50 has six slots 52. Of the six slots 52, four have input/output modules 40 inserted therein, and the remaining two are left as empty spaces (blank). The other configurations are similar to those described in the preceding embodiment (see FIGS. 4 and 5).

### Summary of Second Embodiment

In the present embodiment, as in the preceding embodiment, the input and output module 40 is provided separately from the circuit board 30. The number of input and output modules 40 can be increased or decreased depending on the vehicle model and specifications. In this way, by increasing or decreasing the input and output modules 40, the input and output functions of the zone ECU 12 can be easily changed. There is no need to change the input and output design each time. By increasing or decreasing the number of input and output modules 40, the number of board connection terminals 42 and external connection terminals 43, that is, the number of input and output pins, can be easily changed.

For example, the input and output modules 40 each having a basic unit circuit may be prepared in advance, and the number of input and output modules 40 inserted into slots 52 may be changed depending on the vehicle model and specifications.

The configuration described in the present embodiment can be combined with the configurations described in the preceding embodiment and as modified examples. For example, replacement (changing) and addition or reduction of the input and output modules 40 may be combined.

### Other Embodiments

The disclosure in this specification and drawings is not limited to the exemplified embodiments. The disclosure encompasses the illustrated embodiments and modifications by those skilled in the art based thereon. For example, the disclosure is not limited to the combinations of components and/or elements shown in the embodiments. The disclosure may be implemented in various combinations. The disclosure may have additional portions that may be added to the embodiments. The disclosure encompasses omission of components and/or elements of the embodiments. The disclosure encompasses the replacement or combination of components and/or elements between one embodiment and another. The disclosed technical scope is not limited to the description of the embodiments. It should be understood that some disclosed technical ranges are indicated by description of claims, and includes every modification within the equivalent meaning and the scope of description of claims.

The disclosure in the specification, drawings and the like is not limited by the description of the claims. The disclosures in the specification, the drawings, and the like encompass the technical ideas described in the claims, and further extend to a wider variety of technical ideas than those in the claims. Therefore, various technical ideas can be extracted from the disclosure of the specification, the drawings and the like without being limited to the description of the claims.

When an element or a layer is described as “disposed above” or “connected”, the element or the layer may be directly disposed above or connected to another element or another layer, or an intervening element or an intervening layer may be present therebetween. In contrast, when an element or a layer is described as “disposed directly above” or “directly connected”, an intervening element or an intervening layer is not present. Other terms used to describe the relationships between elements (for example, “between” vs. “directly between”, and “adjacent” vs. “directly adjacent”) should be interpreted similarly. As used herein, the term “and/or” includes any combination and all combinations relating to one or more of the related listed items. For example, the term A and/or B includes only A, only B, or both A and B.

Spatial relative terms “inside”, “outside”, “back”, “bottom”, “low”, “top”, “high”, etc. are used herein to facilitate the description that describes relationships between one element or feature and another element or feature. Spatial relative terms can be intended to include different orientations of a device in use or operation, in addition to the orientations depicted in the drawings. For example, when the device in the figure is flipped over, an element described as “below” or “directly below” another element or feature is directed “above” the other element or feature. Therefore, the term “below” can include both above and below. The device may be oriented in the other direction (rotated 90 degrees or in any other direction) and the spatially relative terms used herein are interpreted accordingly.

Although an example of the CPU included in the microcomputer 321 is shown as the processor, the processor is not limited to this configuration. An MPU, a GPU, a DFP, or the like can be used. The MPU is an abbreviation of a micro-processing unit. The GPU is an abbreviation of a graphics processing unit. The DFP is an abbreviation of a data flow processor. Moreover, a SoC may be adopted in place of the microcomputer 321. The SoC is an abbreviation of a system-on chip. ASIC, FPGA, etc. may also be used. The ASIC is an abbreviation of an application specific integrated circuit. The FPGA is an abbreviation of a field programmable gate array.

The control program may be stored in a computer-readable non-transitory tangible storage medium as an instruction executed by a computer. As the program storage medium, an HDD, an SSD, a flash memory, or the like can be adopted. The HDD is an abbreviation of a hard disk drive. The SSD is an abbreviation of a solid state drive.

What is claimed is:

1. A vehicle control unit having a gateway function, comprising:
a circuit board having a processor and a power supply circuit;
an input and output module having a plurality of board connection terminals and a plurality of external connection terminals that are electrically connected to an external device and that provide input and output functions to the circuit board; and
a power distribution circuit configured to distribute a power supply, wherein the board connection terminal is electrically connected to the circuit board.

2. The vehicle control unit according to claim 1, further comprising,
a holding member having a slot and being configured to hold the input and output module, wherein
the input and output module is provided corresponding to the slot, and a portion of the input and output module is held in the corresponding slot, and
the external connection terminal is capable of being connected to the external device through the corresponding slot.

3. The vehicle control unit according to claim 2, wherein
the holding member includes a housing that houses the circuit board,
the housing has the slot in a top wall facing the circuit board, and
the external connection terminal is held in place in the corresponding slots of the housing.

4. The vehicle control unit according to claim 2, wherein
the board connection terminal and the external connection terminal extend from a main body of the input and output module,
the holding member includes an internal holding member that is housed in a housing together with the circuit board,
a body portion of the input and output module is inserted into the corresponding slot of the internal holding member.

5. The vehicle control unit according to claim 1, further comprising,
communication circuits in multiple systems.

6. The vehicle control unit according to claim 1, further comprising,
a plurality of types of communication circuits.

7. The vehicle control unit according to claim 6, wherein
the plurality of types of communication circuits include at least two of a CAN circuit, an ETHERNET circuit, and a LIN circuit.

8. The vehicle control unit according to claim 1, wherein
the processor performs an input and output for a plurality of devices having different functions.

9. The vehicle control unit according to claim 1, wherein
a plurality of devices having different functions are electrically connected to the external connection terminal.

10. The vehicle control unit according to claim 8, wherein
the plurality of devices are at least two of a body ECU, a powertrain ECU, a cockpit ECU, and an ADAS ECU.

11. The vehicle control unit according to claim 1, wherein
the circuit board has a plurality of inserted portions into which the board connection terminals are inserted to electrically connect the board connection terminals to the circuit board, and
the number of the inserted portions is greater than the number of the board connection terminals.

12. The vehicle control unit according to claim 1, wherein
the input and output module includes a power supply module electrically connected to a battery, and
a diameter of the board connection terminal connected to the battery is longer than the diameter of the other board connection terminals, and the diameter of the external connection terminal connected to the battery is longer than the diameter of the other external connection terminals.

13. The vehicle control unit according to claim 12, wherein
the power supply module handles a maximum direct current of 60 A or more.

14. The vehicle control unit according to claim 1, wherein
the input and output module extends in a direction intersecting a mounting surface of the circuit board on which the processor is mounted.

15. The vehicle control unit according to claim 1, wherein
a plurality of the input and output modules are provided.

16. The vehicle control unit according to claim 15, wherein
each of the input and output circuit, the power distribution circuit, and the communication circuit is provided in any one of the plurality of input and output modules.

17. The vehicle control unit according to claim 1, wherein
a wire harness is connected to the external connection terminal.

18. The vehicle control unit according to claim 17, wherein
the input and output module has a current monitoring circuit that monitors a current flowing through the wire harness and turns off a switch to cut off the current flow when an overcurrent occurs.

19. The vehicle control unit according to claim 1, wherein
the board connection terminal is connected to the circuit board in an insertable and removable manner.

20. The vehicle control unit according to claim 1, wherein
the board connection terminal is soldered to a through-hole land of the circuit board.
